(19) United States
(12) Patent Application Publication
(10) Pub. No.: US 2007/0184195 A1
(43) Pub. Date: Aug. 9, 2007

(54) MASK FILM FORMATION METHOD AND MASK FILM FORMATION APPARATUS

(75) Inventors: Hideyuki Hatakeyama, YOKOHAMA-SHI (JP); Shuichi Yabu, KAWASAKI-SHI (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, TOKYO (JP)

(21) Appl. No.: 11/624,305

(22) Filed: Jan. 18, 2007

(30) Foreign Application Priority Data
Feb. 3, 2006 (JP) 2006/026483

(51) Int. Cl. B05D 1/32; C23C 16/00

(52) U.S. Cl. 427/282; 118/720

(57) ABSTRACT

A substrate and a mask are closely adhered to each other with a high alignment accuracy. While the both ends of the substrate are sandwiched between a substrate supporting member and a planar member, the center portion of the substrate is bent in a convex fashion by means of a substrate pressing member. On a mask pedestal, the mask is also bent in a convex fashion with respect to the substrate by means of a mask pressing member. After alignment in the plane direction between the mask and the substrate is performed, the mask and the substrate are made to approach each other and the convex portion is closely adhered to each other at an initial stage, and then the respective whole surfaces of the mask and the substrate are closely adhered to each other, while the substrate pressing member and the mask pressing member are moved backward. The mask pressing member may be omitted.

### BACKGROUND OF THE INVENTION

1. Field of the Invention

The present invention relates to a mask film formation method and a mask film formation apparatus for forming a desired film on a substrate through an opening in a mask with, the mask being closely adhered to the substrate, by vacuum deposition, spattering, CVD or the like.

2. Description of the Related Art

In recent years, organic EL displays have been put to practical use. As a method of forming Red, Green and Blue pixels of an organic EL display, mask deposition is generally utilized for painting each group of color pixels. The mask deposition is a pattern film formation method in which, with a mask in contact with the film-formation side of a substrate, deposition substances evaporated from a deposition source are deposited through the mask at predetermined positions.

Accordingly, in order to perform the deposition on desired positions, it is required to accurately position (or to make accurate alignment of) the substrate and the mask and then closely adhere the mask and the substrate to each other.

As a method for aligning a substrate and a mask, as disclosed in Japanese Patent Application Laid-Open No. 2004-27291 and Japanese Patent Application Laid-Open No. H11-158605, apparatuses have been proposed that each have correction means for determining the respective positions for a substrate and a mask and appropriately correcting the position of the substrate or the mask.

However, in the case where the methods disclosed in Japanese Patent Application Laid-Open Nos. 2004-27291 and H11-158605 are utilized, a positional deviation which exceeds the tolerance may be caused when the substrate and the mask are closely adhered to each other. Moreover, there has been a problem that, in the case where the substrate and the mask are enlarged, the bends of the substrate and the mask are enhanced, whereby completely the substrate and the mask cannot be closely adhered to each other. In addition, in order to suppress the bends of the substrate and the mask so as to make the substrate and the mask closely adhere to each other, a method has been proposed in which, e.g., by pressing the substrate by means of an elastic member on the peripheral portion of a pressing plate provided close to the rear side of the substrate, the substrate is flattened. However, in the case where the surface of the substrate is originally deformed, it is required to preliminarily cancel the deformation so as to ensure the flatness of the substrate.

In addition, when a magnet behind the substrate pulls up the mask while the mask is bent, the positional deviation exceeding the tolerance may be caused. As an apparatus for suppressing the foregoing mask bend, e.g., Japanese Patent Application Laid-Open No. H11-158605 proposes an apparatus having a mask suction body for magnetically and temporarily sucking the mask, and however the apparatus cannot evenly control the bend of the substrate. As a result, close adhesion between the flattened mask and the substrate cannot be controlled appropriately, whereby the positional deviation exceeding the tolerance may be caused. Additionally, an unadhered portion may be produced between the substrate and the mask, thereby causing invasion by the deposition substance.

As described above, with regard to a method of closely adhering a mask to the surface of a substrate on which a film is to be formed and forming a patterned film through the mask, there has been proposed no method or apparatus that meets the recent requirements for a larger substrate and higher patterning resolution.

In addition, in order to improve the patterning accuracy, the temperatures of a substrate and a mask are required to be controlled during film formation. However, because the temperature control has a limitation under thermal radiation in a vacuum and the temperature is required to be controlled while the substrate and the mask are in contact with each other, it is necessary, also for that reason, to realize close adhesion between the substrate and the mask.

In other words, there are problems such as the bends of a substrate and a mask, the high-accuracy alignment between the substrate and the mask and ensuring close adhesion between the substrate and the mask, accompanied by a problem of controlling the temperatures of the substrate and the mask.

### SUMMARY OF THE INVENTION

An object of the present invention is to provide a mask film formation method and a mask film formation apparatus in which positional deviation due to the bend of a substrate or a mask and defective adhesion between a substrate and a mask are reduced, thereby being able to improve the accuracy in patterning and meet the enlargement of a substrate.

Thus, the present invention provides a film formation method for forming a film on a substrate by applying a film forming material through an opening of a mask, including an alignment step of bending at least one of the substrate and the mask and aligning the substrate and the mask with each other along a ridge-line portion; a line contact step of bringing the substrate and the mask into contact with each other along the ridge-line portion; and a face contact step of bringing the substrate and the mask into face contact with each other.

After, along at least one ridge-line portion where the substrate and the mask are closest to each other, the alignment of the substrate and the mask is performed, the substrate and the mask are closely adhered to each other, initially along at least one of the respective ridge-line portions of the substrate and the mask. By gradually enlarging the close adhesion area between the substrate and the mask from at least one ridge-line portion, as the starting point, where the substrate and the mask are closely adhered initially to each other at the alignment position, the whole close adhesion of the substrate and the mask is enabled while maintaining a given alignment accuracy.

It is desirable that alignment marks for the foregoing alignment be provided at two points on at least one of the respective ridge-line portions of the substrate and the mask and at the corresponding points opposing the two points.

As long as a amount of bend is stable when the substrate and the mask are supported, it is not necessary to limit the postures of the substrate and the mask, and the postures of the substrate and the mask may be different from each other.

Means may be provided by which, in the case where the alignment of the substrate and the mask is performed, a planar member is disposed on a side of the substrate opposite to the mask and, with the substrate bent, the substrate and the planar member are pressed at the positions that are symmetric with respect to the ridge-line portion and furthest from the mask.

By providing the planar member and the substrate pressing means, it is made possible to stabilize the bend of the substrate, thereby realizing reproducible alignment.

Moreover, means may be provided by which any one of the substrate and the mask is held flat without including any bend. By preliminarily holding one of the substrate and the mask unbent, the bend of the other one is stabilized so as to become a constant state, the high-reproducibility alignment is performed, and eventually, it is facilitated to closely adhere the substrate and the mask to each other in an unbent state.

In the case where the substrate is situated above the mask, it is desirable that the mask be preliminarily held in a horizontal and flat state.

Magnetic suction means may be provided by which, after the substrate and the mask are closely adhered to each other over the whole surface, the substrate and the mask are fixed to each other by means of a magnetic force. In addition, by providing the magnetic suction means with temperature control means, the temperatures of the substrate and the mask can be controlled even in a vacuum.

Further features of the present invention will become apparent from the following description of exemplary embodiments with reference to the attached drawings.

### BRIEF DESCRIPTION OF THE DRAWINGS

FIGS. 1A and 1B are schematic diagrams each showing a mask film formation apparatus utilized in Example 1 or Example 4.

FIG. 2 is a plan view showing the position of a substrate supporting member and alignment marks in FIG. 1.

FIG. 3 is a view showing the shape of an alignment mark in a substrate.

FIG. 4 is a view showing the openings (mask pattern) of a mask and alignment marks.

FIGS. 5A and 5B are views for explaining comparative examples.

### DESCRIPTION OF THE EMBODIMENTS

The best mode for embodying the present invention will be explained with reference to the drawings. In the first place, reference characters marked in the drawings will be explained.

Reference numerals 10 denotes a substrate, 11 a substrate supporting member, 12 a substrate pressing member, 13 a planar member, 14 a planar-member pressing member, 15 and 23 magnets, 20 a mask, 21 a mask pedestal, and 22 a mask pressing member.

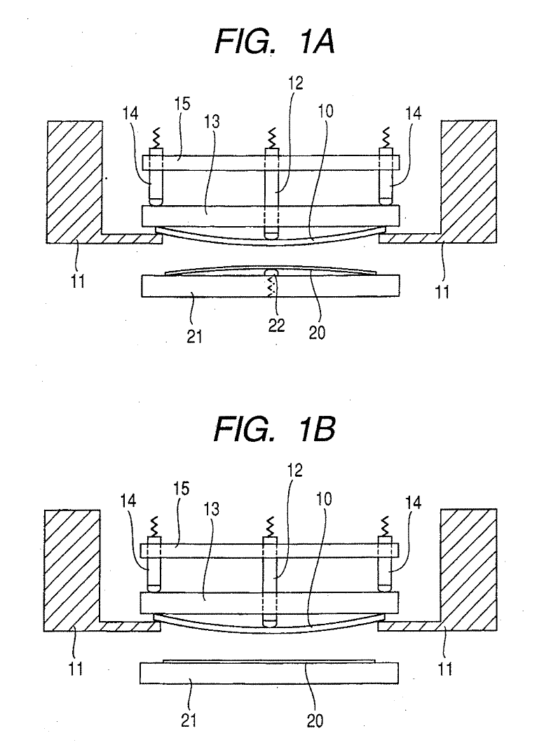

FIGS. 1A and 1B each illustrate a mechanism, in a mask film formation apparatus according to an embodiment, for making the substrate 10 and the mask 20 closely adhere to each other. The mechanism is installed in a vacuum chamber where film formation is performed, in a chamber where alignment is performed, or in the air where a given cleanness level is maintained.

As the substrate 10, a silicon substrate or a plastic substrate may be utilized, depending on the objective. For a display, a substrate is utilized in which drive circuits and pixel electrodes are preliminarily formed on a non-alkali glass.

The mask 20 has openings and is thin plate-shaped. In a film-formation step in which a pattern of higher resolution is required, it is preferable that the thickness of the mask be thin; in general, a mask of 100 μm or smaller in thickness is utilized. In addition, as a material for the mask 20, a magnetic material such as Ni or a Ni—Co alloy is utilized in many cases; openings are formed through the etching method or the electroforming method. There may be a case in which the mask is utilized being fixed in a mask frame not shown while tension is applied to the mask.

High-rigidity bars (not shown) made of an Inver or the like may be prepared so that the accuracy in the opening shape and the position of each mask is enhanced. Specifically, a mode is suitably utilized in which, with bars made of an Inver provided beside the openings of a frame that holds a whole mask, respective partial thin film masks are arranged in areas (to each of which the openings of a whole mask are substantially allocated) surrounded by the bars. The method is preferable in the case where, by cutting a large substrate on which a film has been formed, small substrates are obtained. For example, the method is preferable in the case where a plurality of display panels are obtained by cutting a large-size substrate.

In FIGS. 1A and 1B, the substrate 10 is supported by the substrate supporting member (substrate support means) 11 fixed to a rigid body not shown. In this case, the substrate 10 is supported being bent by its own weight. The state of the bend differs depending on the positions, the shapes and the sizes of the substrate supporting members 11.

In addition, when the substrate 10 is supported, the substrate pressing member (substrate pressure means) 12, which can elastically move forward and backward, may be pressed, from behind the substrate, against the portion, of the substrate 10, where the bending amount is largest so as to stabilize the convex shape caused by the bend of the substrate 10.

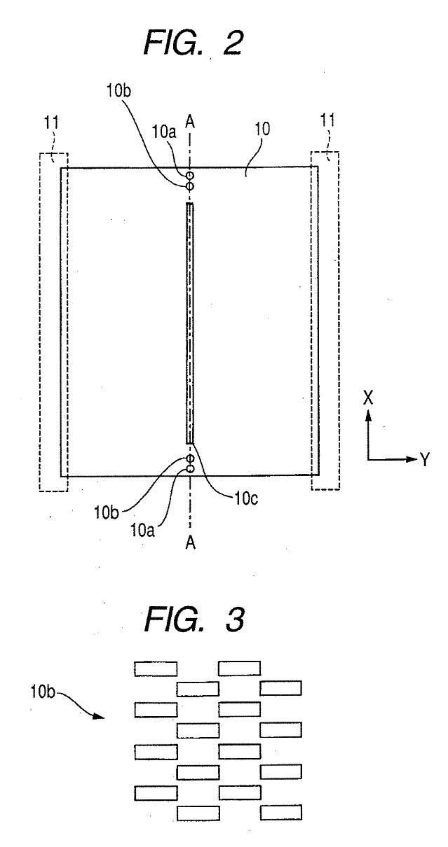

As shown in FIG. 2, in order that, by supporting two sides, in the Y direction, of the substrate 10, the substrate 10 is held so as to be bent most along the center line A in the substrate 10, the substrate pressing member 12 is pressed against the rear side of the substrate 10, at both ends 10a, on the center line (ridge line) A and in the X direction, of the substrate 10, or in a line-shaped area 10c including the center line (ridge line) A. As a result, the bend of the substrate 10 is further stabilized to a fixed shape. In addition, as shown in FIG. 3, patterned alignment marks 10b are provided at both ends of the center line (ridge line) A in the substrate 10.

Moreover, as shown in FIG. 1, with the planar member 13 provided behind the substrate 10, the planar-member pressing member 14 may be pressed, from behind the planar member 13, against the portions, of the planar member 13, where the substrate 10 and the planar member 13 abut on each other so that the bend of the substrate 10 is stabilized.

By disposing the planar member 13 in such a way as to be parallel to the mask pedestal (mask support means) 21, the positional relationship between the substrate 10 and the mask 20 can be regulated. As shown in FIG. 2, when two sides, of the substrate 10, opposing each other are supported, the substrate 10 can be held in such a way as to be bent most along the center line A in the substrate 10, with respect to the mask 20.

In the structure shown in FIG. 1A, at the place (the ridge line portion of the substrate) where the bending amount of the substrate 10 is largest, the mask 20 is held, in such a way as to be bent in a convex fashion with respect to the substrate 10, by the mask pressing member (mask pressure means) 22 that is provided at a side, of the mask 20, opposite to the side opposing the substrate 10 and that can elastically move forward and backward.

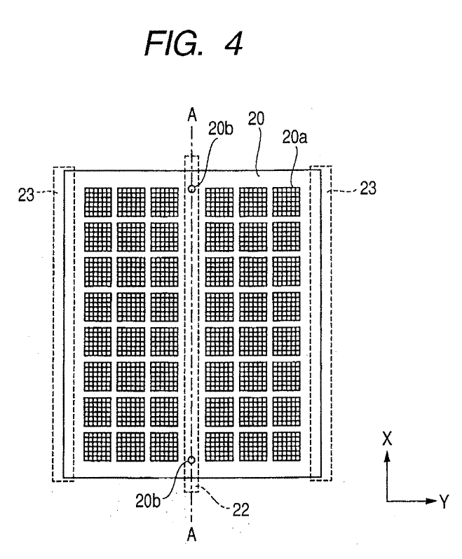

The structure may be such that the magnets 23 are provided as shown in FIG. 4, and the positions of the both ends of the mask 20 are regulated at the portions where the mask 20 and the mask pedestal 21 abut on each other. In other words, when two sides, of the mask 20, opposing each other are regulated by the magnets 23 and the portion, along the center line A, of the mask 20 is pressed by the mask pressing member 22, the mask 20 can be supported in such a way as to be bent most along the center line A, in a convex fashion with respect to the substrate 10. The magnets may be either permanent magnets or electromagnets.

Additionally, either the substrate 10 or the mask 20 may be supported flat. For example, as shown in FIG. 1B, the mask 20 may be held flat on the mask pedestal 21.

As shown in FIG. 2, the respective alignment marks 10b may be arranged at two positions that are symmetric with each other with respect to the center of gravity of the substrate 10. In addition, the respective alignment marks 20b may be arranged at two positions that are symmetric with each other with respect to the center of gravity of the mask 20.

The alignment marks 10b of the substrate 10 and the alignment marks 20b of the mask 20 are detected by position detection means (such as a CCD) not shown, and by positioning means (an alignment mechanism) not shown, the respective positions, in the direction of the substrate plane, of the alignment marks 10b are aligned to the corresponding positions, in the direction of the mask plane, of the alignment marks 20b while the substrate and the mask are kept in no contact with each other. With the alignment positions maintained, the substrate 10 and the mask 20 approach each other, with the assistance of moving means not shown, and come into contact with each other along at least one of the ridge-line portions where the substrate 10 and the mask 20 are closest to each other. When the substrate 10 and the mask 20 are made to further approach each other, the substrate 10 and the mask 20 closely adhere to each other.

It is desirable that the mask pressing member 22 weaken its pressing force at the moment when firstly the substrate 10 and the mask 20 closely adhere to each other, or while gradually the substrate 10 and the mask 20 closely adhere to each other, and eventually create the state in which the surface of the mask 20 conforms to the plane of the mask pedestal 21. Accordingly, the substrate 10 and the mask 20 can closely adhere to each other in the state in which they are not bent but flat.

The pressing force of the substrate pressing member 12 may be released when the substrate 10 and the mask 20 have completely closely adhered to each other.

The planar member 13 may be made to abut on the rear side of the substrate 10 after the substrate 10 and the mask 20 have closely adhered flat to each other.

Moreover, by making the planar member 13 abut on the rear side of the substrate 10 and then making the magnet 15 as magnetic suction means abut on the rear side of the planar member 13, the substrate 10 may be fixed being inserted between the mask 20 and the planar member 13.

The magnet 15 may be either a permanent magnet or an electromagnet. In the case of an electromagnet, the magnet 15 may be controlled in such a way as to generate magnetic force after completely abutting on the planar member 13.

Alternatively, only the magnet 15 may be utilized, with the planar member 13 omitted. When the planar member 13 abuts on the substrate 10, or when the magnet 15 abuts on the planar member 13, the substrate pressing member 12 may be maintained to press the rear side of the substrate 10.

A temperature adjustment mechanism not shown may be provided on the planar member 13 or the magnet 15.

### EXAMPLE 1

Mask film formation was implemented by use of the apparatus in FIG. 1A.

As the substrate 10, a non-alkali glass of 400 mm×500 mm in area and 0.6 mm in thickness was utilized. In the substrate 10, Cr electrodes formed as a pattern though the photolithography step and the alignment marks 10b formed as shown in FIG. 3 were arranged. The pattern of the Cr electrodes was formed in the size of 50 μm×150 μm.

As the mask 20, a thin film mask of 430 mm×530 mm in area and 50 μm in thickness was formed in accordance with the electroforming method and utilized. As the material for the mask 20, Ni was employed. The alignment marks 20b in the mask 20 were formed so as to be the same in position and size as alignment marks 10b, which was made of the Cr electrodes, of the substrate 10. The alignment marks 20b in the mask 20 were formed concurrently with the step of forming the mask pattern (openings) 20ashown in FIG. 4.

The experiment was carried out, with the apparatuses shown in FIGS. 1A and 1B installed in a vacuum.

In the first place, the substrate 10 was set in the substrate supporting members 11. The substrate supporting member 11 had a mechanism for supporting the longitudinal sides of the substrate 10. In this situation, the substrate 10 was bent most and forms a ridge-line portion, along the line A-A that connects the respective centers of the transverse sides. Moreover, the rear side of the substrate 10, which was supported by the substrate supporting member 11, was pressed by the substrate pressing member 12. In this situation, the substrate 10 was maintained to be bent most along the line A-A that connects the respective centers of the transverse sides.

Next, the planar member 13, which was disposed behind the substrate, was made to abut on the substrate 10. In that case, the abutting occurred at the portions that were the highest in the substrate 10, i.e., the longitudinal-side portions of the substrate 10. Additionally, the planar member 13 was pressed against the substrate 10, by the planar-member pressing members 14, which were disposed behind the planar member 13.

Meanwhile, the mask 20 was set on the mask pedestal 21 that was installed horizontally. On that occasion, the mask 20 and the mask pedestal 21 were fixed to each other, by use of electromagnets installed at the longitudinal sides of the mask 20. Additionally, the mask 20 was pressed upward by the mask pressing member 22 disposed along the line A-A that connects the respective centers of the transverse sides of the mask 20, so that, along the line A-A that connects the respective centers of the transverse sides of the mask 20, a ridge-line portion was formed that was most bent in a convex shape with respect to the substrate 10.

With the substrate 10 and the mask 20 set as described above, the alignment marks 10b and the alignment marks 20b of the substrate 10 and the mask 20, respectively, were made to approach corresponding monitors so as to be within the focal depths of the monitors, and then the alignment, in the plane direction, of the substrate 10 with the mask 20 was performed by means of an alignment mechanism, while the alignment marks 10b and 20b were monitored with a CCD camera.

Additionally, the substrate supporting member 11 was gradually moved vertically, so that the substrate 10 and the mask 20 were made to come into contact with each other. When the substrate 10 and the mask 20 came into a contact with each other, the pressing force of the planar-member pressing member 14, which was pressing the planar member 13 against the substrate 10, was released. Additionally, the substrate supporting member 11 was moved vertically, so that the substrate 10 and the mask 20 were made to gradually come into contact with each other, and the pressing force of the mask pressing member 22 was gradually released. Accordingly, the state was formed in which, on the mask pedestal 21 held horizontally, the mask 20 and the substrate 10 were held horizontally and closely adhered to each other.

In this state, measurement indicated that the amount of the positional deviation between the substrate 10 and the mask 20 was within a practical tolerance (within 10 μm), over the whole surface of the substrate 10. The experiment was performed 100 times; the positional deviation in each experiment was within the practical tolerance, over the whole substrate surface.

### EXAMPLE 2

In accordance with the same procedure as that in Example 1, the state was formed in which, on the mask pedestal 21 held horizontally, the mask 20 and the substrate 10 were held horizontally and closely adhered to each other.

Additionally, the planar member 13 disposed behind the substrate was made to abut on the rear side of the substrate, and after the electromagnets disposed behind the planar member 13 were made to abut on the planar member 13, the electromagnets applied magnetic force to the mask. On that occasion, until the magnetic force of the electromagnet was applied, the pressing force of the substrate pressing member 12 was maintained. Additionally, the mask pedestal 21 was gradually moved vertically, so that the mask 20, the substrate 10, the planar member 13 and the electromagnets were integrated to produce a non-bent state.

In this state, measurement indicated that the amount of the positional deviation between the substrate 10 and the mask 20 was within a practical tolerance, over the whole surface of the substrate. The experiment was performed 100 times; however, the positional deviation in each experiment was within the practical tolerance, over the whole substrate surface.

### EXAMPLE 3

In accordance with the same procedure as that in Example 2, the mask 20, the substrate 10, the planar member 13 and the electromagnets were integrated to produce a non-bent state. The mechanism was such that a coolant path is provided inside the planar member 13, and coolant water whose temperature was controlled to 23° C. was continuously supplied.

In this state, a deposition source (not shown) disposed 300 mm under the mask 20 was heated, so that a deposition material (Alq3: manufactured by Dojin Chemistry) was deposited through the mask 20 on the substrate 10. On that occasion, the temperature, at the opening, of the deposition source was 315° C.

The 100 consecutive experiments related to the deposition were carried out. After the deposition, the substrate 10 was taken out from the vacuum; measurement indicated that the amount of the positional deviation between the film formed as a pattern on the substrate surface (on the Cr electrode) and the Cr electrode on the substrate 10 was within a practical tolerance, i.e., within 10 μm, over the whole substrate. The experiment was performed 100 times; however, the positional deviation in each experiment was within the practical tolerance, over the whole substrate surface.

### EXAMPLE 4

Mask film formation was implemented by use of the apparatus shown in FIG. 1B. In the first place, the substrate 10 was set in the substrate supporting members 11. The substrate supporting member 11 supported the longitudinal sides of the substrate 10; the substrate 10 formed a ridge-line portion, along the line connecting the respective centers of the transverse sides, where the bend of the substrate was largest. Moreover, the rear side of the substrate 10, which was supported by the substrate supporting member 11, was pressed by the substrate pressing member 12. On that occasion, the substrate 10 was maintained to be bent most along the line A-A that connects the respective centers of the transverse sides. Additionally, the planar member 13, which was disposed behind the substrate, was made to abut on the substrate 10. In that case, the abutting occurred at the portions that were the highest in the substrate 10, i.e., the longitudinal-side portions of the substrate 10.

Additionally, the planar member 13 was pressed against the substrate 10, by the planar-member pressing members 14, which were disposed behind the planar member 13. On that occasion, the substrate 10 was maintained to be bent most along the line A-A that connects the respective centers of the transverse sides.

Meanwhile, the mask 20 was set on the mask pedestal 21 that was installed horizontally. On that occasion, the mask 20 was fixed by use of electromagnets in such a way as to conform to the surface of the mask pedestal 21.

With the substrate 10 and the mask 20 set as described above, the alignment marks 10b and the alignment marks 20b of the substrate 10 and the mask 20, respectively, were made to approach corresponding monitors so as to be within the focal depths of the monitors, and then the alignment, in the plane direction, of the substrate 10 with the mask 20 was performed by means of an alignment mechanism, while the alignment marks 10b and 20b were monitored with a CCD camera.

Additionally, the substrate supporting member 11 was gradually moved vertically, so that the substrate 10 and the mask 20 were made to come into contact with each other.

Additionally, the substrate supporting member 11 was gradually moved in the vertical direction so as to make the mask 20 and the substrate 10 closely adhere to each other, so that the state was formed in which, on the mask pedestal 21 held horizontally, the mask 20 and the substrate 10 were held horizontally and closely adhered to each other.

In this state, measurement indicated that the amount of the positional deviation between the substrate 10 and the mask 20 was within the practical tolerance, over the whole surface of the substrate. The experiment was performed 100 times; however, the positional deviation in each experiment was within the practical tolerance, over the whole substrate surface.

### COMPARATIVE EXAMPLE

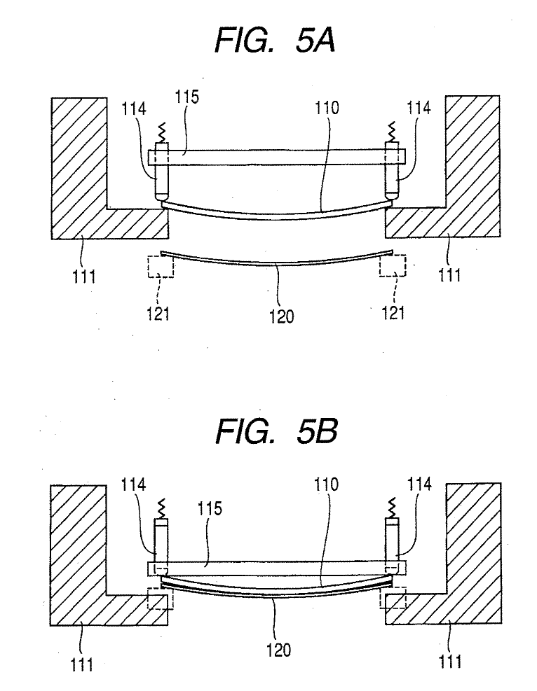

Mask film formation was implemented by use of the apparatus shown in FIGS. 5A and 5B.

In the first place, reference numerals in the figures will be explained. Reference numerals 110, 111, 114, 115, 120 and 121 denote a substrate, substrate supporting members, pressure means, a magnet, a mask and mask supporting members, respectively. Firstly, as shown in FIG. 5A, the substrate 110 was set in the substrate supporting members 111. The substrate supporting members 111 had a mechanism for supporting the longitudinal sides of the substrate 110. On that occasion, due to its own weight, the substrate 110 was bent most, along the line that connects the respective centers of the transverse sides. Additionally, the pressing members 114 disposed behind the substrate 110 was pressed against the both side portions of the substrate 110.

Meanwhile, the mask 120 was set in the mask supporting members 121. The mask supporting members 121 were configured in such a way as to support the four sides of the mask 120.

With the substrate 110 and the mask 120 set as described above, the alignment marks of the substrate 110 and the alignment marks of the mask 120 were made to approach corresponding monitors so as to be within the focal depths of the monitors, and then the alignment, in the plane direction, of the substrate 110 with the mask 120 was performed by means of an alignment mechanism, while the alignment marks were monitored with a CCD camera. Additionally, the substrate supporting member 111 was gradually moved vertically, so that the substrate 110 and the mask 120 were made to gradually come into contact with each other.

FIG. 5B illustrates the state on that occasion. Unadhered (defective adhesion) portions between the substrate 110 and the mask 120 were observed from the center portion to the peripheral portion of the substrate. In addition, when, in this state, the measurement of the amount of the positional deviation between the substrate 110 and the mask 120 was performed, positional deviations exceeding a practical tolerance were observed over the whole surface of the substrate; the extent of the positional deviation was high, especially at the peripheral portion of the substrate. The experiment was performed 100 times and ended up with unstable film formation such that positional deviations within the practical tolerance as well as positional deviations exceeding the practical tolerance were observed.

Additionally, the electromagnet 115 disposed behind the substrate was made to abut on the substrate 110, and then applied magnetic force to the mask. On that occasion, a space was observed between the substrate 110 and the electro magnet 115. In this state, the number of unadhered (defective adhesion) portions was reduced; however, when the measurement of the amount of the positional deviation between the substrate 110 and the mask 120 was performed, positional deviations exceeding the practical tolerance were observed over the whole surface of the substrate, and the extent of the positional deviation was high, especially at the peripheral portion of the substrate. The experiment was performed 100 times and ended up with unstable film formation such that positional deviations within the practical tolerance as well as positional deviations exceeding the practical tolerance were observed.

Additionally, the configuration was such that a coolant path is provided inside the electromagnet 115, and coolant water whose temperature was controlled to 23° C. was continuously supplied. In this state, a deposition source (not shown) disposed 300 mm under the mask 120 was heated, so that a deposition material (Alq3: manufactured by Dojin Chemistry) was deposited through the mask 120 on the substrate 110. On that occasion, the temperature, at the opening, of the deposition source was 315° C. The 100 consecutive experiments related to the deposition were carried out.

After the deposition, the substrate 110 was taken out from the vacuum; the measurement of the amount of the positional deviation between the film formed as a pattern on the substrate surface (on the Cr electrode) and the Cr electrode indicated unstable film formation such that positional deviations within the practical tolerance as well as positional deviations exceeding the practical tolerance were observed.

In addition, with repetition of the deposition, the amount of the positional deviation was enlarged more and more, whereby the rise in the temperatures of the substrate 110 and the mask 120 was indicated.

The present invention is utilized, especially in mask deposition of organic light emitting elements; however, the present invention can widely be applied to deposition apparatuses for other organic compounds or the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims priority from Japanese Patent Application No. 2006-026483 filed Feb. 3, 2006, which is hereby incorporated by reference herein.

What is claimed is:

1. A film formation method for forming a film on a substrate by applying a film forming material through an opening of a mask, the method comprising:
an alignment step of bending at least one of the substrate and the mask, and making the substrate and the mask align with each other along a ridge-line portion;
a line contact step of bringing the substrate and the mask into contact with each other along the ridge-line portion; and
a face contact step of bringing the substrate and the mask into face contact with each other.

2. The film formation method according to claim 1, wherein the line contact step has a step of abutting a planar member on the bent substrate or mask at a symmetric position with respect to a ridge line of the ridged-line portion.

3. The film formation method according to claim 1, wherein the face contact step further includes a step of fixing the substrate and the mask which are in face contact with each other through magnetism.

4. The film formation method according to claim 1, wherein the line contact step is a step of bringing the substrate and the mask into contact with each other along the ridge-line portion by use of a pressing means.

5. A mask film formation apparatus for forming a film on a substrate through an opening in a mask with the mask being closely adhered to the substrate, the apparatus comprising:
a substrate supporting means for supporting the substrate in a state that the substrate is bent in a convex fashion; and
a mask supporting means for supporting the mask,
wherein, in the state that the substrate is bent in a convex fashion, the substrate supporting means and the mask supporting means are made to approach each other, a ridge-line portion of the substrate and the mask are brought into contact with each other, and then the substrate and the mask are closely adhered to each other.

6. The mask film formation apparatus according to claim 5, further comprising a magnetic suction means for fixing the substrate and the mask in a state that the substrate and the mask are closely adhered to each other.

7. A mask film formation apparatus for forming a film on the substrate through an opening with the mask being closely adhered to the substrate, the apparatus comprising:
a mask support means for supporting the mask;
a mask pressing means, capable of moving forward and backward, for bending the mask supported by the mask support means in a convex fashion; and
a substrate supporting means for supporting the substrate,
wherein, in a state that the mask is bent in a convex fashion by the mask pressing means, the substrate support means and the mask support means are made to approach each other and a ridge-line portion of the mask and the substrate are brought into contact with each other, and then the substrate and the mask are closely adhered to each other.

8. The mask film formation apparatus according to claim 7, further comprising a magnetic suction means for fixing the substrate and the mask in a state that the substrate and the mask are closely adhered to each other.
